(19) United States
(12) Patent Application Publication
(10) Pub. No.: US 2025/0301751 A1
(43) Pub. Date: Sep. 25, 2025

(54) SEMICONDUCTOR TRANSISTOR DEVICE AND METHOD OF MANUFACTURING THE SAME

(71) Applicant: Infineon Technologies Austria AG, Villach (AT)

(72) Inventors: Christof Altstätter, Amlach (AT); Maximilian Rösch, St. Magdalen (AT); Ingmar Neumann, Villach (AT); Wolfgang Koell, Ledenitzen (AT)

(21) Appl. No.: 19/081,060

(22) Filed: Mar. 17, 2025

(30) Foreign Application Priority Data
Mar. 22, 2024 (DE) 102024108310.7

(51) Int. Cl. H10D 64/23; H10D 30/01; H10D 30/66; H10D 62/10; H10D 64/00; H10D 64/27

(52) U.S. Cl. CPC H10D 64/2527; H10D 30/0297; H10D 30/665; H10D 30/668; H10D 62/102; H10D 64/117; H10D 64/513; H10D 64/516

(57) ABSTRACT

The disclosure relates to a semiconductor transistor device that includes: a source region at a first side of a semiconductor body; a body region below the source region in the semiconductor body; a field electrode region in a field electrode trench; and a contact plug extending into the semiconductor body and having a contact area towards the source region and the body region. An upper section of the contact area makes electrical contact to the source region. A lower section of the contact area makes electrical contact to the body region. The contact area, as viewed in a vertical cross section, has a concave shape in the upper section adjacent the source region and a convex shape in the lower section adjacent the body region.

### TECHNICAL FIELD

The present disclosure relates to a semiconductor transistor device and a method of manufacturing the same.

### BACKGROUND

As a FET, the semiconductor transistor device may comprise a source region and a body region. The source region may be arranged at a first side of a semiconductor body, the body region being disposed below the source region in the semiconductor body. Via a contact plug extending into the semiconductor body, the source region may be contacted and be connected to the body region. This may avoid a floating body region and for instance prevent an intrinsic parasitic bipolar transistor.

### SUMMARY

In an embodiment, an upper section of a contact area of the contact plug makes electrical contact to the source region and a lower section of the contact area makes electrical contact to the body region. As viewed in a vertical cross-section, the contact area may have a concave shape in the upper section adjacent to the source region and a convex shape in the lower section adjacent to the body region. The convex shape in the lower section can for instance be advantageous in view of a lateral distance to a channel region in the body region, i.e. to maintain a certain distance between the channel region and a body contact doping, e.g. p+ doping. The concave shape in the upper section may increase the size of the contact area towards the source region, e.g. reduce a source contact resistance (depending for instance on the contribution of the contact resistance, this may also influence the Ron). In other words, the concave shape of the plug may allow for an additional contact to the source region “from top”. The convex shape of the plug in the lower section may allow for improved current flow characteristics, e.g. have a positive impact on the current “flowlines” (for instance reduction of a pinch off of an electron-current spreading area).

Further embodiments and features are provided in the dependent claims in and the whole disclosure. Therein, the individual features shall be disclosed independently of a specific claim category, the disclosure relates to apparatus and device aspects, but also to method and use aspects. If for instance a device manufactured in a specific way is described, this is also a disclosure of a respective manufacturing process, and vice versa. In general words, an approach of this application is to provide a contact plug with a contact area having a different curvature in an upper and a lower section.

The contact area having a different curvature, e.g. concave versus convex shape, towards the source region and the body region may be advantageous in view of a decreasing cell size, e.g. in case of low voltage devices. In this respect, the transistor device may for instance have a breakdown voltage of at most 50 V, 30 V or 20 V, possible lower limits being for instance 8 V, 10 V or 12 V. In general, however, higher voltage classes are possible as well, further upper limits of the breakdown voltage being for instance 800 V, 600 V, 400 V, 200 V or 100 V.

The “vertical cross-section” relates to a sectional plane parallel to a vertical direction which may lie perpendicular to a surface or layer of the device, for instance perpendicular to the first side of the semiconductor body. “Laterally” refers to the lateral directions perpendicular to the vertical direction. As to its lateral orientation, the sectional plane of the vertical cross-section may in particular lie perpendicular to a sidewall of a field electrode trench extending into the semiconductor body. The concave/convex shape of the contact area as visible in the sectional plane relates to a view from the source and body region, the concave shape being curved/bulged away from the source region and the convex shape being curved/bulged towards the body region.

“Above” /“below” and “upper” /“lower” refer to the vertical direction, wherein “above” means closer to the first side of the semiconductor body and “below” means closer to a vertically opposite second side of the semiconductor body. The “upper section” of the contact area is closer to the first side of the semiconductor body than the “lower section”. The “lower section” of the contact area may in particular be a lowermost section thereof; in other words, the convex shape may reach down to a lower end of the contact plug. At the second side of the semiconductor body, the drain region of the device may be arranged, the device being for instance a vertical transistor having its source region at the first side and its drain region at the vertically opposite second side of the semiconductor body.

Vertically between the body and the drain region, the transistor device may comprise a drift region, for instance made of the same conductivity type like the drain region but with a lower doping concentration. The field electrode trench may extend into the drift region, a field electrode arranged in the trench capacitively coupling to the drift region via a field dielectric at a sidewall of the trench. Together with the field electrode, the field dielectric may form a field electrode region of the device.

As discussed in further detail below, a gate electrode of the device may be arranged in a trench as well, for instance in a separate gate electrode trench aside the field electrode trench or together with the field electrode in the same field electrode trench. Independently of these details, the gate electrode may capacitively couple to the body region via a gate dielectric at a sidewall of the trench, the gate electrode and gate dielectric forming a gate region of the device. By applying a voltage to the gate electrode, a channel formation in the body region may be controlled, e.g. a vertical current flow through the device.

In an embodiment, the contact area as viewed in the vertical cross-section has a laterally protruding shoulder portion following the concave shape. The shoulder portion may rest on the source region, e.g. rest on the first side of the semiconductor body as viewed in the vertical cross-section. The shoulder portion may provide an additional contact to the source region from top and increase the size of the contact towards the source region, thus.

In an embodiment, a backside area of the contact plug lies adjacent to a dielectric in the field electrode trench. As viewed in the vertical cross-section, the backside area of the contact plug lies laterally opposite to the contact area which has the concave/convex shape. As viewed in the vertical cross-section, the convex shape of the contact area may reach towards the backside area, i.e. merge directly into the backside area at the lower end of the contact plug. The dielectric in the field electrode trench may be the field dielectric of the field electrode region or another dielectric above the field electrode, for instance a dielectric isolating a gate electrode arranged in the same trench from the contact plug.

In an embodiment, the backside area as viewed in the vertical cross-section has a laterally protruding shoulder portion resting on the dielectric. In combination with the embodiment discussed above, the contact plug as viewed in the vertical cross-section may have a shoulder portion in the contact area and also in the laterally opposite backside area, the shoulder portions protruding in two opposite lateral directions. The shoulder portion of the backside area may be arranged at a smaller vertical height and/or have a smaller lateral protrusion than the shoulder portion of the contact area.

In an embodiment, the backside area of the contact plug as viewed in the vertical cross-section is asymmetrical to the contact area. This may apply independently of whether or not the contact area or backside area comprises or comprise shoulder portion(s). As viewed in the vertical cross-section, the “asymmetrical” backside area may for instance have no mirror symmetry to the contact area with respect to a vertical axis.

Generally, the contact plug may connect the source and body region to a wiring structure, e.g. metallization, above the first side of the semiconductor body. The wiring structure may be formed on an insulating layer arranged on the first side of the semiconductor body, for instance an oxide layer or layer stack. The contact plug may extend through the insulating layer, e.g. extend in a contact trench formed in the insulating layer.

In an embodiment, a sidewall of the contact trench formed in the insulating layer is covered by a dielectric layer. The dielectric layer may for instance be a silicon oxide layer, e.g. TEOS layer. During manufacturing, it may be applied after the contact trench has been etched into the insulating layer, for instance to fill a recess in a dielectric, wherein the recess results from this etch step, see in further detail below.

In an embodiment, the gate electrode of the device is offset downwards with respect to the first side of the semiconductor body, an upper end of the gate electrode displaced downwards with respect to the first side of the semiconductor body. A contact hole in the insulating layer for connecting the gate electrode to a wiring structure, e.g. metallization, may be formed in the same process step like the contact trench for the contact plug, wherein the offset downwards may lead to an overetch in the contact trench for the contact plug, e.g. lead to the recess in the dielectric in the trench.

The connection to the source region and the body region may be formed in an active area of the device, e.g. in active device cells in which an electrical current flows in operation of the device. Additionally, the device may comprise an inactive area, e.g. with inactive device cells. In the inactive area, a cell or cells having no source region but only a body region may be provided. In embodiment, a further contact plug is provided in the inactive area, which may be of the same type and shape like the contact plug in the active area. The further contact plug may have a contact area with a concave shape in an upper section and a convex shape in a lower section, wherein, in contrast to the contact plug in the active area, also the upper section may lie adjacent to the body region.

In an embodiment, the field electrode trench is a columnar trench in which a columnar field electrode is arranged. The columnar trench may for instance have a vertical extension being larger compared to its lateral extensions, which may also be referred to as a spicular or needle shape. Independently of these details, the gate electrode may be arranged in a separate gate trench aside the field electrode trench, for instance in a gate trench surrounding the columnar trench. The gate trench may define a cell layout of the device, for instance a pattern with a translational symmetry, like a rectangular/quadratic or hexagonal cell pattern.

In an embodiment, the backside area of the contact plug, which lies laterally opposite to the contact area as viewed in the vertical cross-section, lies adjacent to a field dielectric arranged in the columnar field electrode trench. Via the field dielectric, the columnar field electrode may capacitively couple to the drift region, see in detail above.

In an embodiment, the contact trench in the insulating layer as seen in a vertical top view has a surrounding portion which extends around the cell, e.g. forms a closed line around the cell. In addition, a central portion of the contact trench as seen in the vertical top view may extend across the columnar field electrode trench, e.g. for providing a contact to the field electrode. In case of a rectangular or quadratic cell, the surrounding portion may have a rectangular or quadratic shape, the central portion of the contact trench extending for instance in parallel to two side edges of the rectangle or quadrat.

In an embodiment, the field electrode trench has an elongated shape, the field electrode provided as a field plate in the elongated field electrode trench. As seen in a top view, the field plate or elongated field electrode trench may have a stripe shape, the device comprising for instance a plurality of respective stripe shaped cells arranged consecutively, e.g. in a first lateral direction. In general, the elongated field electrode trench may be combined with an elongated gate electrode arranged in a separate trench aside, the device comprising for instance gate and field electrode trenches arranged alternately in the first lateral direction.

In an embodiment, however, the gate electrode is arranged in the same elongated field electrode trench as the field plate, for instance laterally aside and/or above the field plate. In other words, the field plate may be arranged in a lower section of the field electrode trench and the gate electrode may be arranged in an upper section of the field electrode trench, e.g. isolated from the field plate by a dielectric in between. Depending on the design in detail, the entire field plate may be arranged below the gate electrode, e.g. when the field plate is contacted via a resistive element arranged laterally aside the gate electrode in the field electrode trench, see in further detail below.

Alternatively, however, the field plate may have a lower section arranged below the gate electrode and an upper section extending aside the gate electrode in the upper section of the field electrode trench. In this case, the gate electrode as viewed in a sectional plane parallel to the first lateral direction may be arranged at a first side wall of the field electrode trench, wherein the upper section of the field plate extends, at least over a section, on the same height at a second side wall of the field electrode trench (there it can be contacted by the contact plug, see in detail below). Independently of these details, a field electrode trench comprising the field plate and the gate electrode may have a stripe shape as seen in a top view, the device comprising for instance a plurality of respective stripe shaped cells.

In an embodiment, the gate electrode capacitively couples to the body region at a first sidewall of the field electrode trench as viewed in the vertical cross-section. The contact plug may be arranged at a second sidewall of the field electrode trench, wherein the first and the second sidewall lie laterally opposite with respect to the first lateral direction, i.e. transverse direction. Perpendicularly thereto, in a second lateral direction, i.e. length direction, the field electrode trench or field plate may have its length extension.

This embodiment, i.e. of the gate electrode and the contact plug arranged at opposite side walls of the same trench, shall also be disclosed independently of a specific shape of the contact area of the contact plug. In other words, it shall be disclosed: A semiconductor transistor device, comprising: a field electrode region in a field electrode trench extending into a semiconductor body; a contact plug extending into the semiconductor body; wherein the field electrode trench is an elongated trench, the field electrode region comprising a field plate in the elongated field electrode trench, and wherein a gate electrode is arranged in the field electrode trench aside and/or above the field plate, and wherein, as viewed in a vertical cross-section, the gate electrode is arranged at a first side wall of the field electrode trench, the contact plug being arranged at a laterally opposite second side wall of the field electrode trench. As to further embodiments and features, reference is made to the description as a whole. The contact plug may, e.g. alternatively or in addition to contacting for instance a source region and/or body region of the transistor device, for instance be connected to the field electrode, e.g. via a resistive element, see the following description in detail.

In an embodiment, the contact plug is electrically connected to the field plate. As viewed in a vertical cross-section, the backside area of the contact plug, which lies laterally opposite to the contact area of the contact plug, may be connected to or contact the field plate.

In an embodiment, the contact plug is connected to the field plate via a resistive element which is arranged in the field electrode trench. The resistive element may allow for a delayed charging of the field plate, for instance in dynamic switching applications. The resistive element can for instance have a resistance of at least 1 Ω/mm² device area, further lower limits being for example 5 Ω, 10 Ω, 20 Ω, 30 Ω, 40 Ω or 50 Ω, respectively per mm² device area. By way of example, a possible upper limit of the resistance can be 500 Ω2 per mm² device area. The resistive element may have a larger specific resistance than the contact plug and/or the field plate. Like the field plate, the resistive element may be made of polysilicon, e.g. with a lower doping compared to the field plate.

A method of manufacturing a semiconductor transistor device may comprise: forming an insulating layer on a first side of a semiconductor body; etching a contact trench reaching down to the first side of the semiconductor body into the insulating layer, wherein the etching leaves a recess in a dielectric in a trench; filling the recess by depositing a dielectric layer; etching away the dielectric layer from the first side of the semiconductor body in the contact trench; forming a contact plug in the contact trench.

As discussed above, the dielectric layer may be a silicon oxide layer, for instance TEOS layer. In addition to filling the recess, the dielectric layer may also cover the sidewall or sidewalls of the contact trench formed in the insulating layer. In step iv), the dielectric layer may be etched away from the first side of the semiconductor body, i.e. at the bottom of the contact trench in the insulating layer, by anisotropic etching, for instance anisotropic plasma etching. Therein, the dielectric layer at the sidewall or sidewalls of the contact trench may remain as a residuum.

In an embodiment, an additional etching into the semiconductor body at the bottom of the contact trench is applied after step iv) and before step v). With this groove etch into the semiconductor body, the trench or hole for the contact plug can be extended down into the semiconductor body, e.g. allowing for an electrical contact formation from top and from the side.

In an embodiment, a contact plug having a contact area with a concave shape towards a source region and a convex shape towards a body region is manufactured, see the description above in detail.

### BRIEF DESCRIPTION OF THE DRAWINGS

Below, the semiconductor transistor device and its manufacturing are explained in further detail by means of exemplary embodiments. Therein, the individual features can also be relevant in a different combination.

FIG. 1 shows a vertical cross-section of a transistor device with a columnar field electrode trench and a contact plug which electrically contacts a source region and a body region of the device;

FIG. 2 shows a more detailed view of the contact plug of FIG. 1;

FIGS. 3a, b illustrate manufacturing steps for the device of FIG. 1;

FIG. 3c shows a contact trench structure in a vertical top view:

FIG. 4 shows a device with an elongated field electrode trench and a contact plug which contacts a source and a body region of the device;

FIG. 5 illustrates a manufacturing step for the device of FIG. 4;

FIG. 6 shows a further device with an elongated field electrode trench and a contact plug;

FIG. 7 summarizes some manufacturing steps in a flow diagram.

### DETAILED DESCRIPTION

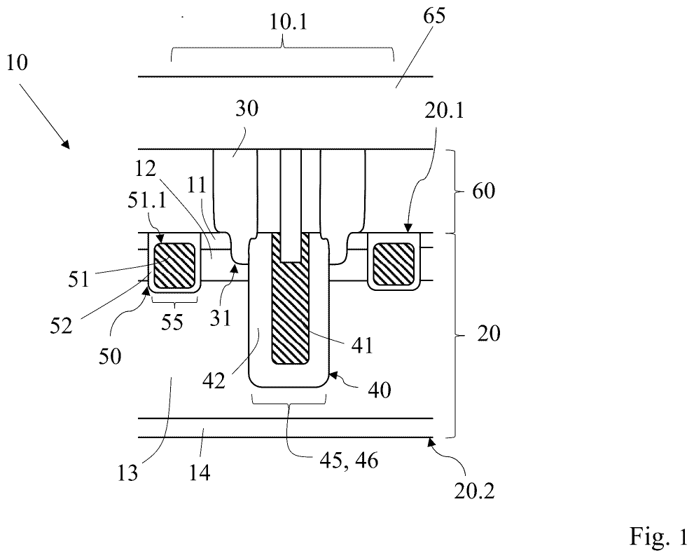

FIG. 1 shows a semiconductor transistor device 10 comprising a source region 11, a body region 12, a drift region 13 and a drain region 14. The source region 11 is arranged at a first side 20.1 of a semiconductor body 20 and the drain region 14 is arranged at a vertically opposite second side 20.2. Laterally aside the body region 12, a gate region 50 is arranged in a trench 55. The gate region 50 comprises a gate electrode 51 and a gate dielectric 52 which capacitively couples the gate electrode 51 to the body region 12. An upper end 51.1 of the gate electrode 51 is offset downwards with respect to the first side 20.1 of semiconductor body 20. Via a gate voltage applied to the gate electrode 51, a vertical current flow through the body region 12 can be controlled.

In a field electrode trench 45, a field electrode region 40 is arranged. The field electrode region 40 comprises a field electrode 41 and a field dielectric 42 which capacitively couples the field electrode 41 to the drift region 13. The source region 11, the drift region 13 and the drain region 14 are made of a first conductivity type, the body region 12 being made of a second conductivity type. The drift region 13 is made of the same doping type as the drain region 14 but with a lower doping concentration. In the example shown, the first type is n-type and the second type is p-type.

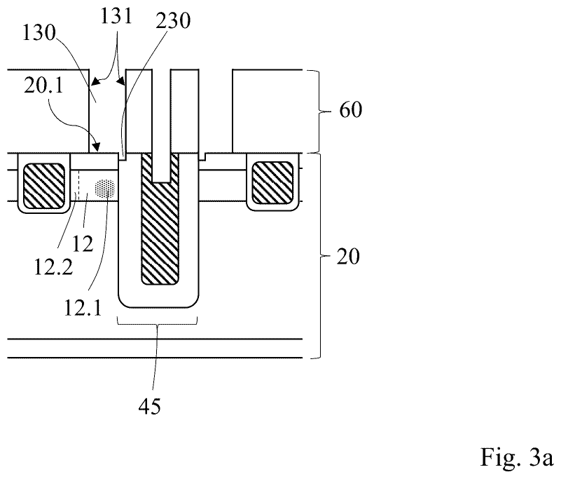

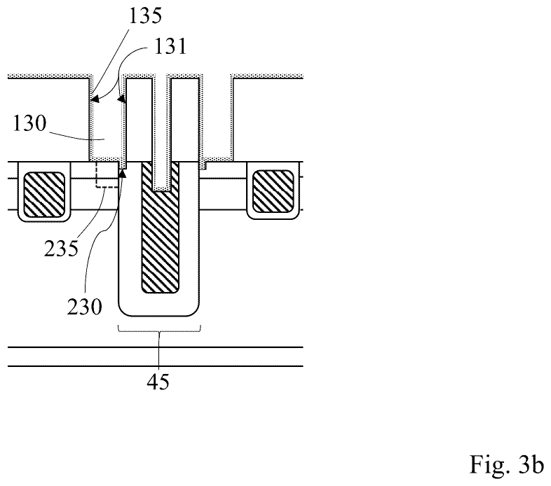

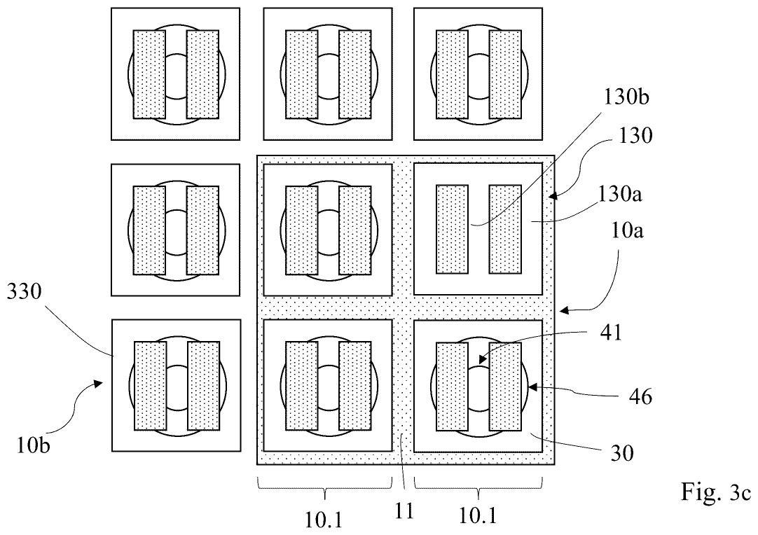

In the embodiment of FIG. 1, the field electrode trench 45 is a columnar trench (see FIG. 3c for comparison). The gate trench 55 surrounding the columnar field electrode trench 46 may define a cell 10.1 of the transistor device 10, e.g. a quadratic cell in the active area of the device.

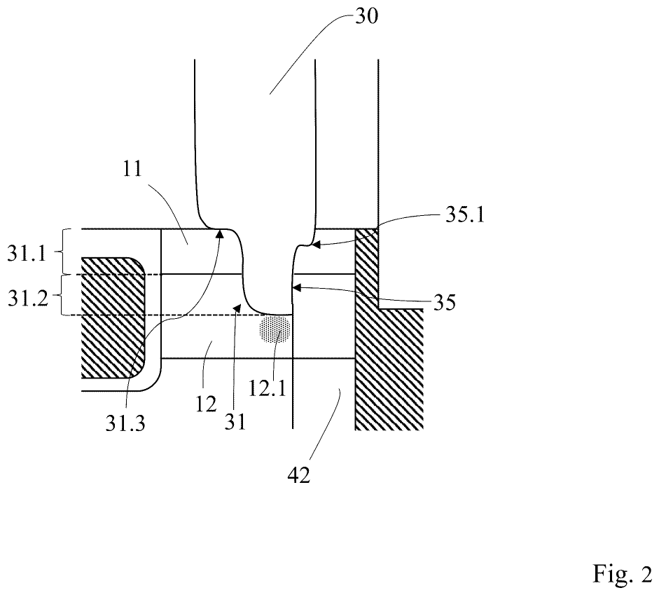

A contact plug 30 extends into the semiconductor body 20 and has a contact area 31 towards the source region 11 and the body region 12, see in detail FIG. 2. The contact plug 30 extends through an insulating layer 60 and connects the source region 11 and the body region 12 to a metallization layer 65 above, which is only shown schematically here.

FIG. 2 shows a detailed view of the contact plug 30 with the contact area 31. An upper section 31.1 of the contact area 31 contacts the source region 11 and a lower section 31.2 of the contact area 31 contacts the body region 12. In the upper section 31.1, the contact area 31 has a concave shape, i.e. is bulged away from the source region 11. In the lower section 31.2, it has a convex shape, i.e. is bulged towards the body region 12. In detail, the contact plug 30 may be connected to the body region 12 via a highly doped body contact region 12.1, e.g. p+ doping in the example shown.

Following the concave shape in the upper section 31.1, the contact area 31 has a laterally protruding shoulder portion 31.3. The shoulder portion 31.3 rests on the source region 11, i.e. provides for an additional electrical contact from top.

As viewed in the vertical cross-section, a backside 35 of the contact plug 30 lies adjacent to the field dielectric 42 in the field electrode trench 45. In the embodiment shown, the backside area 35 has a laterally protruding shoulder portion 35.1 which rests on the dielectric 42. Though having a shoulder portion 35.1 like the contact area 31, the backside area 35 is asymmetrical to the contact area 31.

FIG. 3a shows an intermediate step of manufacturing the contact plug of FIGS. 1 and 2. The insulating layer 60 has been formed on the semiconductor body 20 and a contact trench 130 reaching down to the first side 20.1 of the semiconductor body 20 has been etched where the contact plug is to be formed. To maintain a certain lateral spacing between a channel region 12.2 aside the gate electrode region 50 and the highly doped body contact region 12.1, the contact trench 130 has a lateral position directly aside the field electrode trench 45. In the field dielectric 42, the etching of the contact trench 130 down to the first side 20.1 of the semiconductor body 20 leaves a recess 230.

As illustrated in FIG. 3b, this recess 230 in the field dielectric 42 is subsequently filled by depositing a dielectric layer 135 which is a TEOS layer in the example shown. The dielectric layer 135 fills the recess 230 and also forms on the sidewalls 131 which define the contact trench 130 laterally and at the bottom of the contact trench 130 on the first side 20.1 of the semiconductor body 20. In a subsequent step, the dielectric layer 135 is removed at the bottom of the contact trench 130 from the first side 20.1 of the semiconductor body 20, e.g., by anisotropic plasma etching. Subsequently, an additional etch step may be applied to etch a groove 235 (indicated only schematically in dashed lines) into the semiconductor body 20 before forming the contact plug 30.

FIG. 3c illustrates the contact trench 130 in a vertical top view, i.e. illustrates a plurality of device cells 10.1 each having a field electrode 41 with a columnar shape in a columnar trench 46. On the lower right, an active area 10a of the device 10 is shown, where the source region 11 is connected in each device cell 10.1. Aside and above, an inactive area 10b is shown, where a further contact plug or contact plugs 330 make only contact to a body region (not referenced here). For illustration, in one cell the design or structure of the contact trench 130 in the insulating layer is highlighted. It has a surrounding portion 130a which forms a closed line around the respective device cell 10.1 and a central portion 130b extending across the columnar field electrode trench to provide a contact to the field electrode 41.

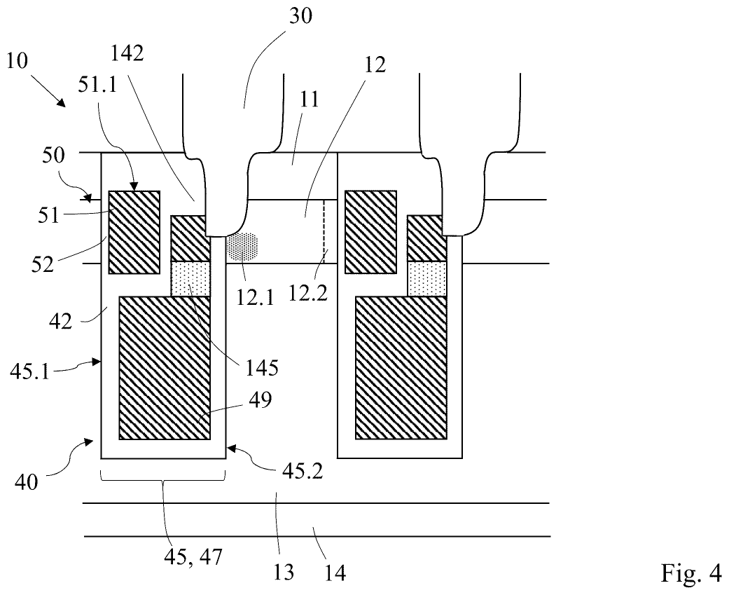

FIG. 4 shows a transistor device 10 with a partly alternative design. Generally, in this disclosure, the like reference numerals indicate the like elements or elements having the like function and reference is made to the description of the other figures as well. The field electrode trench 45 is an elongated trench 47 which has its length extension perpendicular to the drawing plane. The field electrode is a field plate 49 having a respective length extension.

In addition to the different field electrode trench design, the transistor device 10 of FIG. 4 has its gate region 50 in the same field electrode trench 45, 47 above the field plate 49. In an upper portion of the elongated field electrode trench 47, the gate electrode 51 capacitively coupling to the body region 12 is disposed and a lower portion of the elongated field electrode trench 47 extends into the drift region 13 and comprises the field plate 49.

The gate electrode 51 is arranged at a first sidewall 55.1 of the field electrode trench 45, wherein the contact plug 30 is arranged at a laterally opposite second sidewall 45.2. The arrangement at the opposite sidewalls 45.1, 45.2 may have advantages in view of a lateral distance between the high body contact doping 12.1 and the channel region 12.2. In addition to contacting the source region 11 and the body region 12, the contact plug 30 makes electrical contact to the field electrode or field plate 49. The field plate 49 and a contact plug 30 are connected via a resistive element 145 which may have a higher resistance compared to the bulk material of the field plate 49.

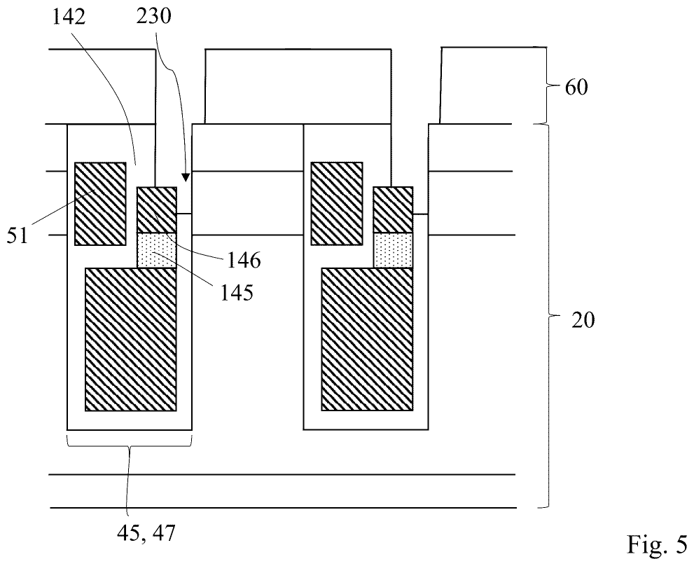

FIG. 5 illustrates an intermediate step when manufacturing the transistor device 10 of FIG. 4, namely after the contact trench 130 has been etched into the insulating layer 60 on the semiconductor body 20. As discussed with reference to FIGS. 3a, b, this leaves a recess 230 in a dielectric 142 in the field electrode trench 45, wherein the dielectric 142 of FIG. 5 isolates the gate electrode 51 from the resistive element 145 and a connection 146 to the resistive element 145. In a subsequent step, the recess 230 is filled by depositing a dielectric layer (not shown), see the description above.

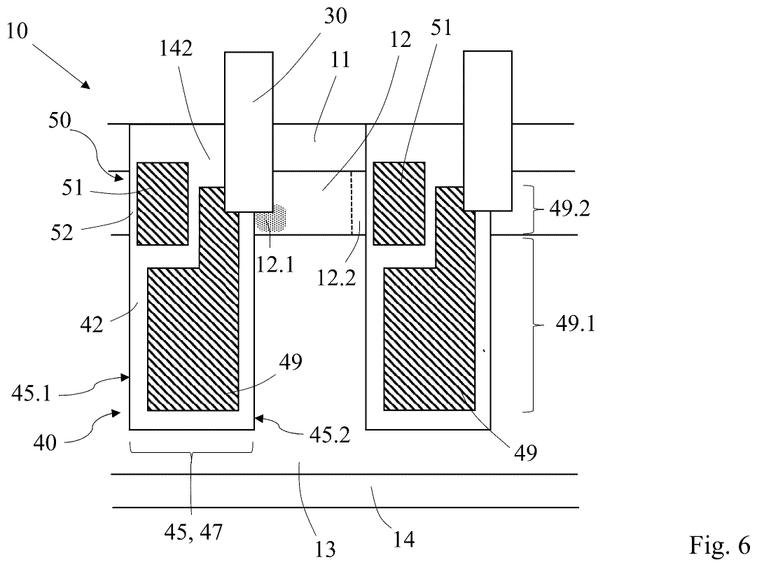

FIG. 6 shows a transistor device 10 with a design comparable in principle to FIG. 4. The contact plug 30 of FIG. 6 has a basically rectangular cross-sectional profile, e.g. does not have a contact area with a combined convex/concave shape. However, alternatively, the same contact plug 30 as shown in FIG. 4 could be implemented to the device 10 illustrated in FIG. 6. In contrast to FIG. 4, the field plate 49 of FIG. 6 extends further upwards in the elongated field electrode trench 47. As illustrated for the field plate 49 on the right, a lower section 49.1 of the field plate 49 is arranged below the gate electrode 51, whereas an upper section 49.2 of the field plate 49 extends aside the gate electrode 51. In the upper section 49.2, the field plate 49 is contacted by the contact plug 30.

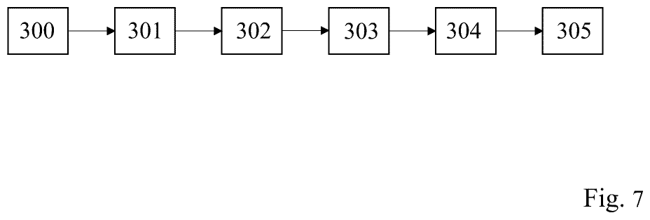

FIG. 7 summarizes some manufacturing steps in a flow diagram. After forming 300 the insulating layer on the first side of the semiconductor body, the contact trench or trenches are etched 301 into the insulating layer. This may leave a recess in a dielectric, see FIGS. 3a and 5 for illustration. The recess is filled 302 by depositing a dielectric layer, wherein the dielectric layer is subsequently etched away 303 at the bottom of the contact trench, i.e. from the first side of the semiconductor body. By etching 304 into the semiconductor body, a groove extending into the source and body region may be formed prior to forming 305 the contact plug.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor transistor device, comprising:
a source region at a first side of a semiconductor body;
a body region below the source region in the semiconductor body;
a field electrode region in a field electrode trench;
a contact plug extending into the semiconductor body and having a contact area towards the source region and the body region,
wherein an upper section of the contact area makes electrical contact to the source region and a lower section of the contact area makes electrical contact to the body region,
wherein the contact area, as viewed in a vertical cross section, has a concave shape in the upper section adjacent the source region and a convex shape in the lower section adjacent the body region.

2. The semiconductor transistor device of claim 1, wherein the contact area, as viewed in the vertical cross section, has a laterally protruding shoulder portion following the concave shape and which rests on the source region.

3. The semiconductor transistor device of claim 1, wherein a backside area of the contact plug, which as viewed in the vertical cross section lies laterally opposite to the contact area, is arranged adjacent to a dielectric in the field electrode trench.

4. The semiconductor transistor device of claim 3, wherein the backside area, as viewed in the vertical cross section, has a laterally protruding shoulder portion which rests on the dielectric.

5. The semiconductor transistor device of claim 1, wherein a backside area of the contact plug, which as viewed in the vertical cross section lies laterally opposite to the contact area, is asymmetrical to the contact area.

6. The semiconductor transistor device of claim 1, wherein the contact plug extends in a contact trench formed in an insulating layer on the first side of the semiconductor body, and wherein a sidewall of the contact trench is covered by a dielectric layer.

7. The semiconductor transistor device of claim 1, further comprising:
a gate region comprising a gate electrode in a trench,
wherein an upper end of the gate electrode is offset downwards with respect to the first side of the semiconductor body.

8. The semiconductor transistor device of claim 1, wherein the contact plug with the contact area is arranged in an active area of the semiconductor transistor device, and wherein in an inactive area of the semiconductor transistor device, a further contact plug having the same shape as the contact plug is provided and makes contact only to the body region of the semiconductor transistor device.

9. The semiconductor transistor device of claim 1, wherein the field electrode trench is a columnar trench.

10. The semiconductor transistor device of claim 9, wherein a backside area of the contact plug, which as viewed in the vertical cross section lies laterally opposite to the contact area, is arranged adjacent to a dielectric in the field electrode trench, and wherein the dielectric is a field dielectric of the field electrode region and capacitively couples the field electrode to the semiconductor body.

11. The semiconductor transistor device of claim 9, wherein the columnar trench is arranged in a transistor device cell, wherein the contact plug is arranged in a contact trench in an insulating layer on the first side of the semiconductor body, and wherein, as seen in a vertical top view, the contact trench has a surrounding portion which extends around the transistor device cell and has a central portion which extends across the columnar trench.

12. The semiconductor transistor device of claim 1, wherein the field electrode trench is an elongated trench, and wherein the field electrode region comprises a field plate in the elongated trench.

13. The semiconductor transistor device of claim 12, wherein a gate electrode of the gate region is arranged in the field electrode trench aside and/or above the field plate.

14. The semiconductor transistor device of claim 13, wherein, as viewed in a vertical cross section, the gate electrode capacitively couples to the body region at a first sidewall of the field electrode trench, and wherein the contact plug is arranged at a laterally opposite second sidewall of the field electrode trench.

15. The semiconductor transistor device of claim 14, wherein the contact plug is electrically connected to the field plate.

16. The semiconductor transistor device of claim 15, wherein the contact plug is electrically connected to the field plate via a resistive element arranged in the field electrode trench.

17. A method of manufacturing a semiconductor transistor device, the method comprising:
forming an insulating layer on a first side of a semiconductor body;
etching a contact trench reaching down to the first side of the semiconductor body into the insulating layer, wherein the etching leaves a recess in a dielectric in a trench;
filling the recess by depositing a dielectric layer;
etching away the dielectric layer from the first side of the semiconductor body in the contact trench; and
forming a contact plug in the contact hole.

18. The method of claim 17, further comprising:
after etching away the dielectric layer from the first side of the semiconductor body in the contact trench and before forming the contact plug in the contact hole, etching into the semiconductor body in the contact hole.

19. The method of claim 17, further comprising:
forming a source region at the first side of the semiconductor body;
forming a body region below the source region in the semiconductor body; and
forming a field electrode region in a field electrode trench,
wherein the contact plug has a contact area towards the source region and the body region,
wherein an upper section of the contact area makes electrical contact to the source region and a lower section of the contact area makes electrical contact to the body region,
wherein the contact area, as viewed in a vertical cross section, has a concave shape in the upper section adjacent the source region and a convex shape in the lower section adjacent the body region.

20. The method of claim 17, further comprising:
forming a gate region comprising a gate electrode in a trench, such that an upper end of the gate electrode is offset downwards with respect to the first side of the semiconductor body.
